(19) United States
(12) Patent Application Publication
(10) Pub. No.: US 2007/0029616 A1
(43) Pub. Date: Feb. 8, 2007

(54) SEMICONDUCTOR INTEGRATED CIRCUIT DEVICE AND METHOD OF FABRICATING THE SAME

(75) Inventor: Young-Ju Choi, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do (KR)

(21) Appl. No.: 11/425,089

(22) Filed: Jun. 19, 2006

(30) Foreign Application Priority Data
Aug. 3, 2005 (KR) 2005-0071066

(51) Int. Cl. H01L 29/76

(52) U.S. Cl. 257/365

(57) ABSTRACT

A semiconductor integrated circuit device and a method of fabricating the same are provided. An embodiment of the semiconductor integrated circuit device includes a substrate having a cell region and a peripheral circuit region. A recess channel transistor may be formed in the cell region and include a source/drain region, a recess channel formed between the source/drain region, a gate insulation layer formed in the recess channel, and a gate formed on the gate insulation layer in a self-aligned manner. A planar channel transistor may further be formed in the peripheral circuit region and include a source/drain region, a planar channel formed between the source/drain region, a gate insulation layer formed in the planar channel, and a gate formed on the gate insulation layer in a self-aligned manner.

### CROSS-REFERENCE TO RELATED APPLICATION

This application claims priority from Korean Patent Application No. 10-2005-0071066 filed on Aug. 3, 2005 in the Korean Intellectual Property Office, the disclosure of which is incorporated herein by reference in its entirety.

### BACKGROUND

1. Field of the Invention

The present invention relates to a semiconductor integrated circuit device and a method of fabricating the same, and more particularly, to a semiconductor integrated circuit device with reduced power consumption and stable operation and a method of fabricating the semiconductor integrated circuit device.

2. Description of the Related Art

MOS (Metal-Oxide Semiconductor) devices are increasingly miniaturized in response to the desire to increase the integration density of semiconductor devices. To this end channel lengths are reduced to deep sub-micron levels, which may further increase the operating speed and current drive capability of the device.

However, as the channel length is reduced, source and drain depletion regions may invade the channel, causing a reduction in the effective channel length and the threshold voltage. This, in turn, causes a short channel effect that may cause problems with the gate control function of the MOS transistors.

Accordingly, recess channel array transistors (RCATs) having an elongated channel by forming a recess channel trench on a region where each channel is to be formed, have been developed.

In manufacturing an RCAT, a recess channel is formed on the active region of a substrate and a gate is then formed above the recess channel. In this case, the active region, the recess channel, and the gate must be precisely aligned with one another in order to guarantee that the RCAT will have stable operation.

The alignment of the active region, the recess channel, and the gate is carried out using an alignment key, which is formed on a mask used to form patterns.

However, if a single mask is repeatedly used in a photographic operation, the alignment key formed on the mask may be deformed because of the high-frequency environment in which the photographic operation is carried out. If the alignment key is deformed, it may be difficult to achieve precise alignment. In addition, transistors to be formed on a single substrate may differ from one another in size and location. Thus, it is difficult to precisely align these transistors with one another when forming them using a single mask.

Once a misalignment occurs, that is the recess channel being misaligned with the gate formed over it, the length of channel decreases. This decrease in the length of the channel may cause various defects in a semiconductor device as discussed above.

In addition, the gate of a typical MOS transistor is formed to have sharp edges. Thus, a strong electric field may be generated near the edges of the gate because of the concentration of electric charges at the edges. Thus, the sharp edges of the gate may serve as parasitic transistors, which may cause a double hump phenomenon, where the MOS transistor is turned on twice. When the double hump phenomenon occurs, the operation of the MOS transistor is abnormal, thus increasing leakage current and consuming a considerable amount of power.

### SUMMARY

Embodiments of the present invention provide a recess semiconductor integrated circuit device which can reduce power consumption and maintain stable operation, as well as providing a method of fabricating the recess semiconductor integrated circuit device.

According to an embodiment of the present invention, a semiconductor integrated circuit device includes a substrate having a cell region and a peripheral circuit region, a recess channel transistor formed in the cell region. The recess channel transistor may further include a source and a drain region, a recess channel formed between the source and the drain regions, a gate insulation layer formed in the recess channel, and a gate formed on the gate insulation layer in a self-aligned manner. The embodiment of the semiconductor integrated circuit device may further include a planar channel transistor formed in the peripheral circuit region. The planar channel transistor includes a source and a drain region, a planar channel formed between the source and the drain regions, a gate insulation layer formed in the planar channel, and a gate formed on the gate insulation layer in a self-aligned manner.

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a semiconductor integrated circuit device according to an exemplary embodiment of the present invention;

FIG. 2 is a flowchart illustrating a method of fabricating a semiconductor integrated circuit device according to the exemplary embodiment of the present invention illustrated in FIG. 1;

FIGS. 3 through 8 are cross-sectional views illustrating a method of fabricating a semiconductor integrated circuit device according to the exemplary embodiment of the present invention illustrated in FIG. 1;

FIG. 9 is a cross-sectional view of a semiconductor integrated circuit device according to another exemplary embodiment of the present invention;

FIGS. 10 through 15 are cross-sectional views illustrating a method of fabricating a semiconductor integrated circuit device according to the exemplary embodiment of the present invention illustrated in FIG. 9;

FIG. 16 is a cross-sectional view of a semiconductor integrated circuit device according to yet another exemplary embodiment of the present invention; and

FIGS. 17 through 24 are cross-sectional views illustrating a method of fabricating a semiconductor integrated circuit device according to the exemplary embodiment of the present invention illustrated in FIG. 16.

### DETAILED DESCRIPTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art. Like reference numerals refer to like elements throughout the specification.

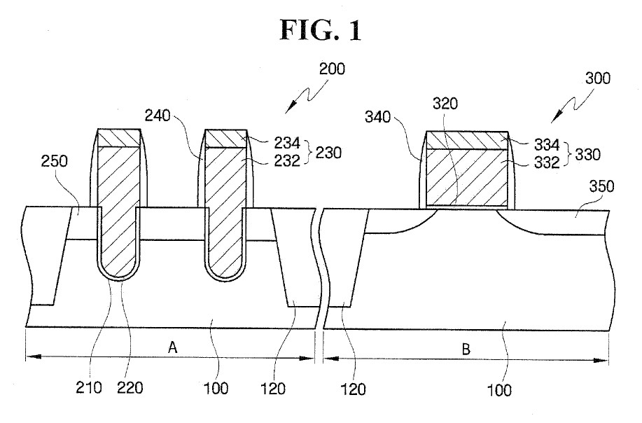

A method of fabricating the semiconductor integrated circuit device according to an exemplary embodiment of the present invention will now be described in detail with reference to FIG. 1. FIG. 1 is a cross-sectional view of a semiconductor integrated circuit device according to an exemplary embodiment of the present invention.

Referring to FIG. 1, a substrate 100 is divided into a cell region A and a peripheral circuit region B. A plurality of recess channel transistors 200 are formed in the cell region A, and a planar channel transistor 300 is formed in the peripheral circuit region B.

Meanwhile, the substrate 100 is also divided into an active region and an inactive region by an isolation layer 120, e.g., a shallow trench isolation (STOOL) layer or a field oxide (FOX) layer.

A recess channel 210 is formed in the active region of the cell region. The recess channel 210 may be formed to a depth of about 1700 to about 1900 Å. In addition, the recess channel 210 may be formed to have a width of about 900 to about 1100 Å. A gate insulation layer 220 is formed on the inner surface of the recess channel 210, and a gate insulation layer 320 is formed on the top surface of the substrate 100 in the peripheral circuit region B. The gate insulation layers 220 and 320 may be formed of silicon oxide or silicon oxynitride and may have a thickness of about 20 to about 80 Å.

A gate 230 is formed on the gate insulation layer 220 in the cell region, and a gate 330 is formed on the gate insulation layer 320 in the peripheral circuit region. In detail, the gate 230 is formed to substantially completely fill the recess channel 220 and protrude above the top surface of the substrate 100 while the gate 330 is formed on the gate insulation layer 320 above the surface of the substrate 100. The gate 230 is formed to be self-aligned with both sidewalls of the recess channel 210, and the gate 330 is formed to be self-aligned with the gate insulation layer 320. In other words, the gate 230, which protrudes over the top surface of the substrate 100, is aligned with a pair of imaginary straight lines extending above each sidewall of the recess channel 210.

The gate 230 may be formed on the gate insulation layer 220 and include a stack of a polysilicon layer 232 and a gate metallic layer 234. Likewise, the gate 330 may be formed on the gate insulation layer 320 and include a stack of a polysilicon layer 332 and a gate metallic layer 334. The polysilicon layer 232 is formed to substantially completely fill the recess channel 210 and protrude to a height of about 600 to about 700 Å above the top surface of the substrate 100. The polysilicon layer 332 may be formed to a height of about 750 to about 900 Å. The gate metallic layers 234, 334 may be formed on the polysilicon layers 232, 332 to a height of about 700 to about 800 Å. The gate metallic layers 234, 334 may be formed of WSi, W, or CoSi.

In addition, source/drain regions 250 and 350 are formed at either side of each of the gates 230 and 330 in the active region by implanting impurity ions. For example, if the substrate 100 is a P-type semiconductor substrate, the source/drain regions 250 and 350 may be formed by implanting N-type impurity ions.

Spacers 240 are formed on both sidewalls of the gate 230, and spacers 340 are formed on both sidewalls of the gate 330. The spacers 240 and 340 may be formed of SiN or SiO₂. Since the gate 230 is formed in a self-aligned manner, the gate can be prevented from being misaligned with the recess channel 220 even when an alignment key formed on a mask is deformed. In addition, since the gate 230 is formed in a self-aligned manner, it can be aligned with the recess channel 220 even when the respective recess channel transistors slightly differ from each other in size and location.

In other words, a sufficient channel length can be secured by preventing the gate 230 from being misaligned with the recess channel 220 and preventing the gate 330 from being misaligned with the gate insulation layer 320. Thus, the recess channel transistor 200 and the planar channel transistor 300 can provide stable operation.

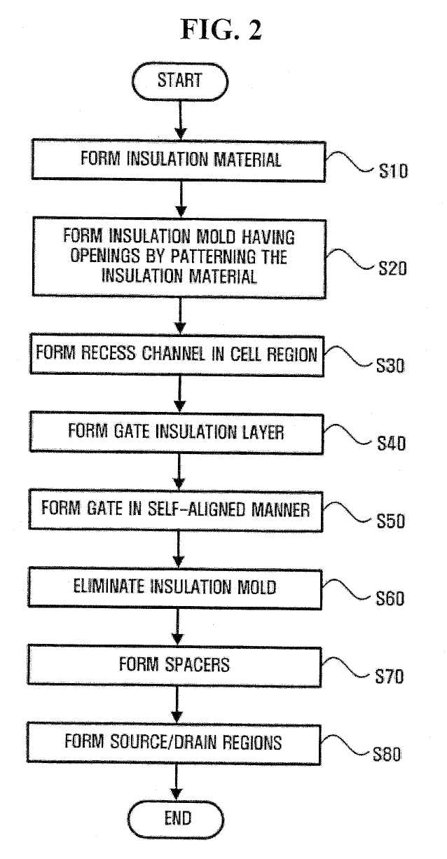

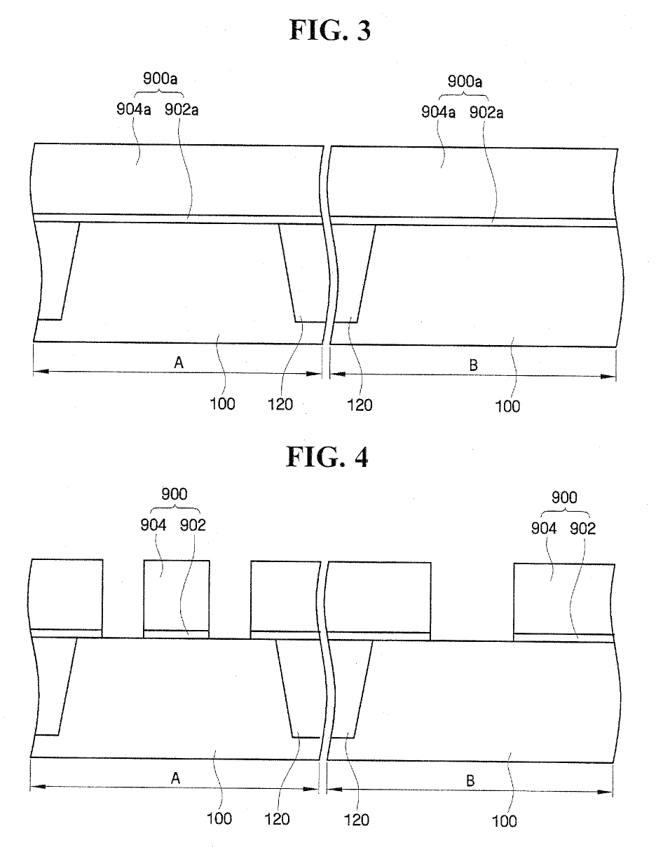

Hereinafter, referring to FIGS. 1 through 8, a method of fabricating the semiconductor integrated circuit device according to an exemplary embodiment of the present invention will now be described in detail. FIG. 2 is a flowchart illustrating a method of fabricating a semiconductor integrated circuit device according to an exemplary embodiment of the present invention. FIGS. 3 through 8 are cross-sectional views illustrating a method of fabricating the semiconductor integrated circuit device of FIG. 1 according to an exemplary embodiment of the present invention.

Referring to FIGS. 2 through 8, the substrate 100 is first divided into an active region and an inactive region by an isolation layer 120, e.g., an STI layer. The substrate 100 is also separated into a cell region A and a peripheral circuit region B.

Next, in operation S10, an insulation material 900a is formed on a substrate 100 as illustrated in FIG. 3. The insulation material 900a has a double-layer structure consisting of an upper insulation material 904a and a lower insulation material 902a. The lower insulation material 902a serves as an etching stopper layer and may be formed as a SiN layer. The upper insulation material 904a may be formed of an oxide.

For example, the insulation material 900a may be formed as a medium temperature oxide (MTO) layer at a temperature of about 400° C. The insulation material 900a may be deposited on the substrate 100 to have a thickness of about 1000 to about 7000 Å. In order to form gates in a self-aligned manner, the thickness of the insulation material 900a must be greater than the height of the gates in consideration of the possibility of the insulation material 900a being partially etched away during the formation of the gates to be formed. Therefore, the insulation material 900a may be formed to be about 200 Å thicker than the gates to be formed.

Thereafter, in operation S20, an insulation mold 900 is formed having a plurality of openings, as illustrated in FIG. 4, by patterning the insulation material 900a. The insulation mold 900 is patterned by performing etching on the insulation mold 900 until the top surface of the substrate 100 is exposed. Lower insulation mold 902, which is an etching stopper layer, is etched away together with the upper insulation mold 904 during this etching process.

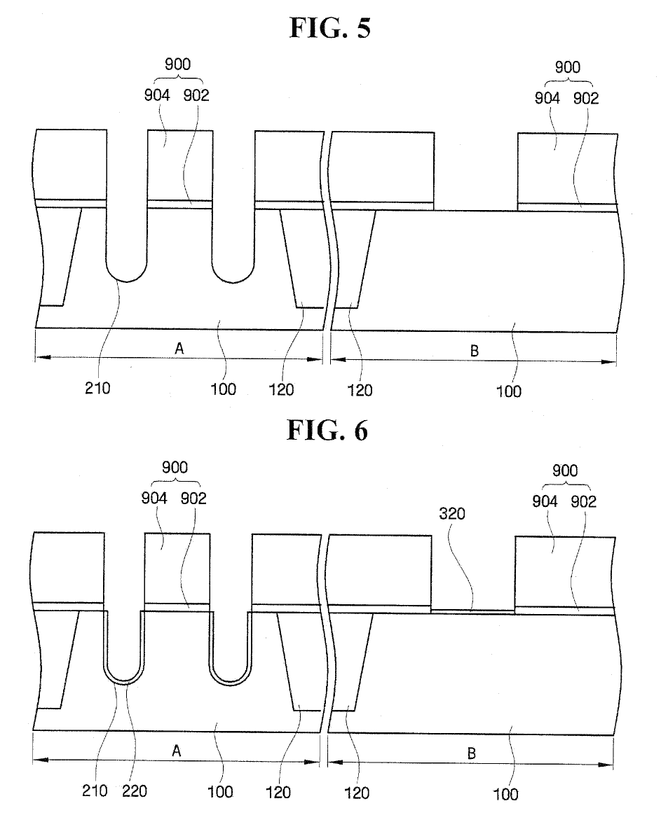

In operation S30, the recess channel 210 is formed in the cell region A as illustrated in FIG. 5. In detail, the recess channel 210 is formed by etching the substrate 100 in the cell region A to a predetermined depth using the insulation mold 900 of FIG. 4 as an etching mask. Before the formation of the recess channel 210, a photoresist may be formed on the substrate 100 in the peripheral circuit region B so that the substrate 100 in the peripheral circuit region B can be protected from the etching operation performed in the cell region A. After the formation of the recess channel 210, the photoresist is removed from the peripheral circuit region B through, for example, ashing.

As shown in FIG. 6, in operation S40, a gate insulation layer 220 is formed on the inner surface of the recess channel 210, and a gate insulation layer 320 is formed on the top surface of the substrate 100 in the peripheral circuit region B. The gate insulation layers 220 and 320 may be formed of silicon oxide or silicon oxynitride. The gate insulation layers 220 and 320 may be formed by supplying oxygen or nitrogen onto the inner surfaces of the recess channel 210 and the substrate 100 in the peripheral circuit region B exposed through the openings in the insulation mold 900 so that a thin film can grow on the inner surface of the recess channel 210 and on the substrate 100 in the peripheral circuit region B exposed through the openings as a result of the reaction of silicon with oxygen or nitrogen.

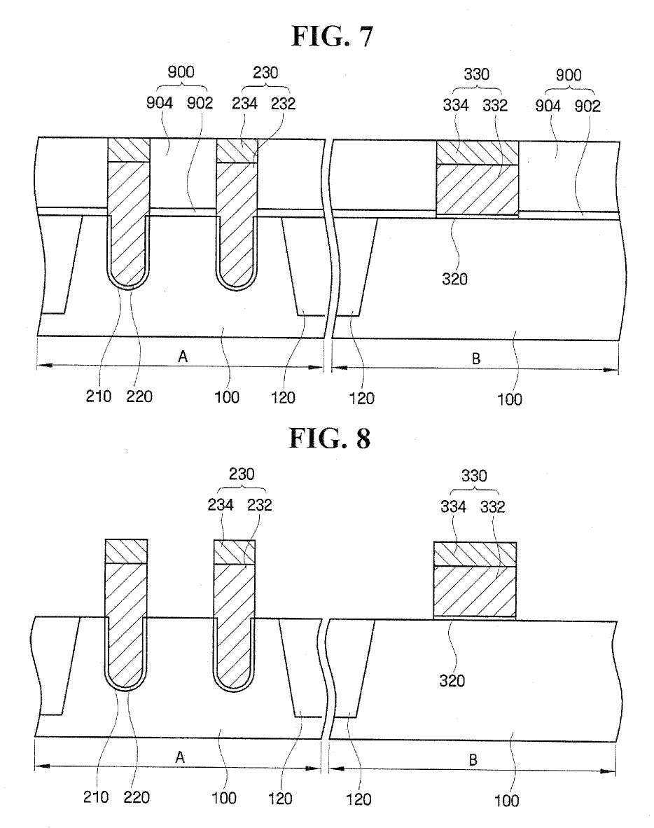

As shown in FIG. 7, in operation S50, gates 230 and 330 are formed on the gate insulation layers 220 and 320, respectively. In detail, polysilicon layers 232 and 332 are formed on the gate insulation layers 220 and 320, respectively. The polysilicon layer 232 in the cell region A may be formed so as to substantially completely fill the recess channel 210. Further, the openings in the insulation mold 900 may be substantially completely filled with the polysilicon layers 232 and 332. Thereafter, gate metallic layers 234 and 334 are deposited on the polysilicon layers 232 and 332, respectively. Next, an etch-back operation is performed to form the gates 230 and 330. During the etch-back operation, upper portions of the insulation mold 900 may be slightly etched. The gates 230 may be formed in the cell region A to substantially completely fill the recess channel 210 and the openings in the insulation mold 900. The gate 330 may be formed in the peripheral circuit region B to substantially completely fill the openings in the insulation mold 900.

Referring to FIG. 8, in operation S60, the insulation mold 900 is removed and the formation of the gate 230 self-aligned with both sidewalls of the recess channel 210 is completed. That is, the gate 230 protruding over the top surface of the substrate 100 is self-aligned with both sidewalls of the recess channel 210, and in particular aligned with a pair of imaginary straight lines extending above both sidewalls of the recess channel 210.

Referring to FIG. 1, in operation S70, pairs of spacers 240 and 340 are formed on both sidewalls of the gates 230 and 330, respectively. The spacers 240 and 340 are formed by depositing a nitride layer (e.g., a SiN layer) or an oxide layer (e.g., a SiO2 layer) through chemical vapor deposition (CVD) and anisotropically etching the nitride layer or the oxide layer.

Thereafter, in operation S80, source/drain regions are formed by implanting impurity ions into the active region on either side of each of the gates 230 and 330 as illustrated in FIG. 1. In detail, the source/drain regions are formed by implanting ions into the exposed substrate 100 and may be formed to extend under at least a portion of the spacers 440 and 540 as shown in FIG. 1. If the transistors 200 and 300 of FIG. 1 are N-type MOS transistors, the source/drain regions may be formed by implanting a high concentration of asbestos (As) or phosphor ions with energy of several tens of keV. On the other hand, if the transistors 200 and 300 of FIG. 1 are P-type MOS transistors, the source/drain regions may be formed by implanting a high concentration of boron (B) ions with energy of several tens of KeV.

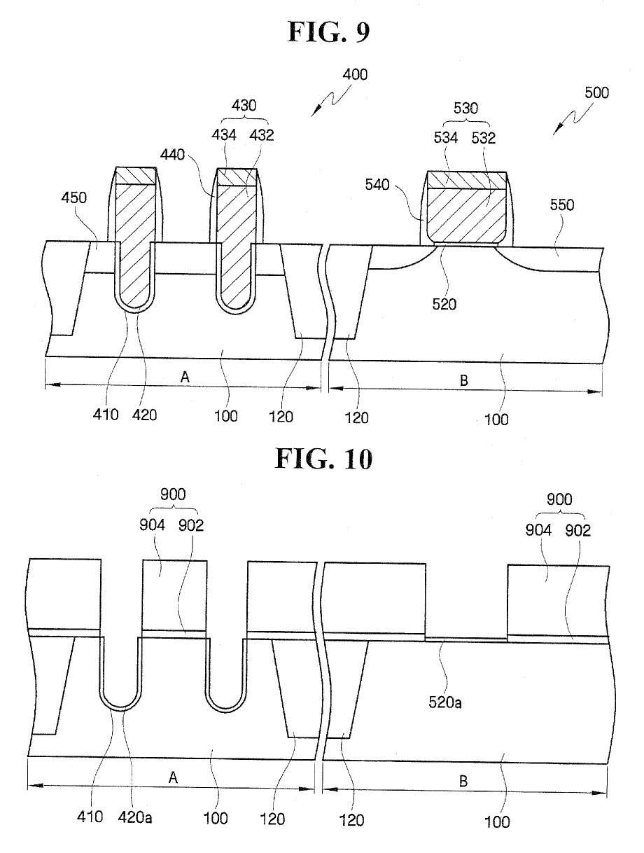

Hereinafter, referring to FIG. 9, a method of fabricating the semiconductor integrated circuit device according to another exemplary embodiment of the present invention will now be described in detail. FIG. 9 is a cross-sectional view of a semiconductor integrated circuit device according to another exemplary embodiment of the present invention. The semiconductor integrated circuit device of FIG. 9 has a similar structure to the semiconductor integrated circuit device of FIG. 1.

Referring to FIG. 9, a gate insulation layer 420 is formed on the inner surface of the recess channel 410 in a cell region A, while a gate insulation layer 520 is formed between the substrate 100 and the planar channel transistor 500 in the peripheral circuit region B. The gate insulation layers 420 and 520 may be formed of silicon oxide (SiOx) or silicon oxynitride (SiON). The gate insulation layer 420 may be thicker than the gate insulation layer 520. Gates 430 and 530 are provided on the gate insulation layers 420 and 520, respectively.

The gate 430 of the recess channel transistor 400 fills the recess channel 410 and protrudes above the top surface of the recess channel 410. The gate 530 of the planar channel transistor 500 is stacked over the gate insulation layer 520. Here, the gate 430 of the recess channel transistor 400 is self-aligned with the recess channel 410. That is, the gate 430 protruding above the recess channel transistor 400 is aligned with a pair of imaginary straight lines extending above both sidewalls of the recess channel 410.

In addition, the gate 530 of the planar channel transistor 500 is formed on the gate insulation layer 520. In particular, the gate 530 is undercut so that the width of the gate 530 at the bottom is the same as the width of the gate insulation layer 520, as shown in FIG. 9.

Additionally, the edges of the lower portions of the gate 530 may be generally rounded.

The thickness of the gate insulation layer 420 is different from the thickness of the gate insulation layer 520 in order to differentiate the voltage at which the recess channel transistors 400 are driven from the voltage at which the planar channel transistor 500 is driven and to further differentiate the electrical characteristics of the recess channel transistors 400 from the electrical characteristics of the planar channel transistor 500.

If the gate 530 of the planar channel transistor 500 is formed to have generally rounded undercut lower portions, it is possible to prevent a strong electric field from being concentrated upon edges of the gate 530. Therefore, it is possible to stabilize the operation of the planar channel transistor 500 and reduce leakage current. In addition, it is possible to reduce the power consumption of the planar channel transistor 500 by securing a sufficient amount of time to refresh the planar channel transistor 500.

A method of fabricating the semiconductor integrated circuit device according to an exemplary embodiment of the present invention will now be described in detail with reference to FIGS. 10 through 15.

Referring to FIGS. 10 through 15, a substrate 100 is divided into an active region and an inactive region, and recess channels 410 are formed in a cell region A using an insulation mold 900 in the same manner as described above with reference to FIGS. 3 through 5.

Thereafter, referring to FIG. 10, a first oxide layer 420a is formed on the inner surface of each of the recess channels 410 exposed through openings formed in the insulation mold 900, and a first oxide layer 520a is formed on the top surface of the substrate 100 in a peripheral region B exposed through an opening formed in an insulation mold 900.

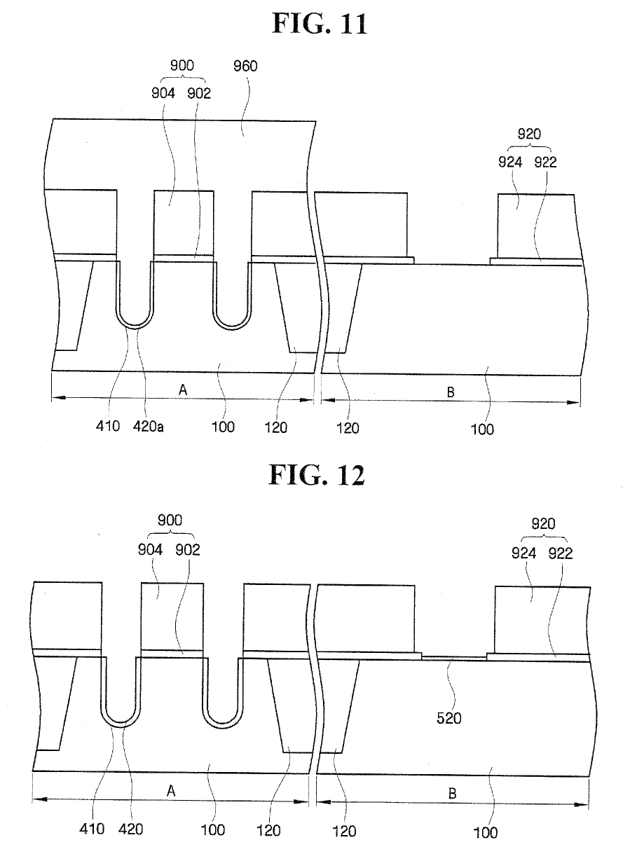

Thereafter, referring to FIG. 11, photoresist 960 is applied onto the top surface of the substrate 100 in the cell region A, and an isotropic etching operation is preformed on the substrate 100 to eliminate the first oxide layer 520a in the peripheral circuit region B. If part of the insulation mold 920 is formed of an oxide layer, the insulation mold 920 may be partially etched together with the first oxide layer 520a. In other words, if the insulation mold 920 has a 2-layered structure consisting of a lower insulation mold 922 and an upper insulation mold 924 formed as an oxide layer, the lower insulation mold 922 may serve as an etching stopper layer, part of the upper insulation mold 924 may be eliminated together with the first oxide layer 520a, and thus, the width of the opening in the insulation mold 920 may be increased. Accordingly, the insulation mold 920 may have a step structure as illustrated in FIG. 11.

Thereafter, referring to FIG. 12, the photoresist 960 is eliminated from the cell region A through, for example, ashing. Further, an oxidation operation may be performed on the first oxide layers 420a and on the top surface of the substrate 100 in a peripheral region B exposed through an opening formed in an insulation mold 920, thereby forming gate insulation layers 420 and 520. Since the gate insulation layer 420 in the cell region A is obtained through two oxidation operations and the gate insulation layer 520 in the peripheral circuit region B is obtained through one oxidation operation, the gate insulation layer 420 is thicker than the gate insulation layer 520.

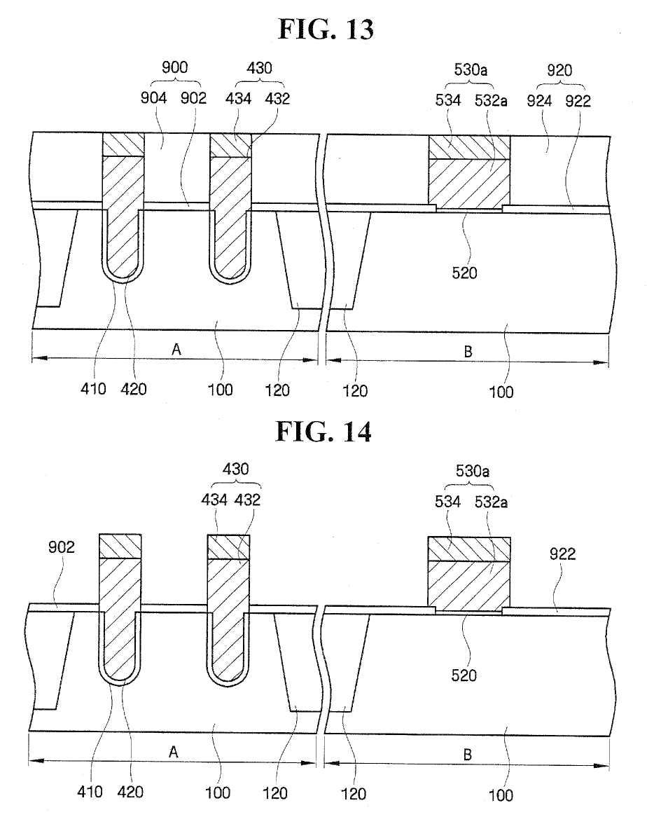

Thereafter, referring to FIG. 13, gates 430 are formed in the cell region A in a self-aligned manner to substantially completely fill the openings in the insulation mold 900, and a gate 530a is formed in the peripheral circuit region B in a self-aligned manner to substantially completely fill the opening in the insulation mold 920.

Here, the opening in the insulation mold 920 in the peripheral circuit region B has a step structure, and thus, the gate 530a is formed to have a step-like profile.

Thereafter, referring to FIG. 14, the insulation molds 900 and 920 are eliminated through etching. If each of the insulation molds 900 and 920 has a 2-layered structure, only an upper insulation mold 904 and the upper insulation mold 924 are eliminated while keeping a lower insulation mold 902 and the lower insulation mold 922 intact.

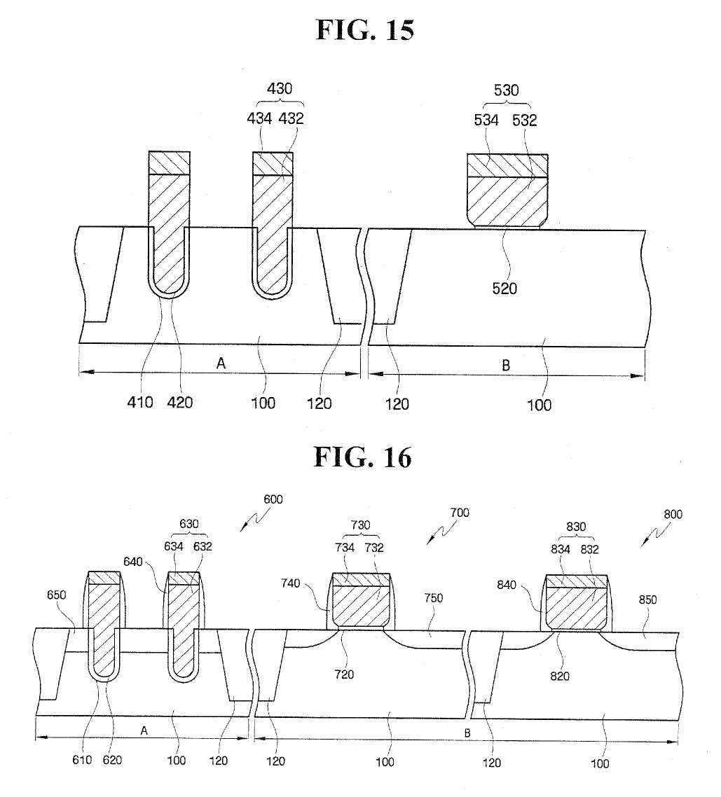

Thereafter, referring to FIG. 15, the lower insulation molds 902 and 922 are eliminated by performing an isotropic etching operation. The isotropic etching operation is carried out using an etchant which is capable of slightly etching the polysilicon layers 432 and 532 as well as the lower insulation molds 902 and 922. Thus, when the lower insulation molds 902 and 922 are eliminated, the polysilicon layers 432 and 532 may be slightly etched. Further, the more a target of an etching operation protrudes, the more it may be affected by an etchant. Thus, lower portions of the polysilicon layer 532 may be generally rounded in the isotropic etching operation.

Thereafter, spacers 440 and 540 and then sources and drain regions 450 and 550 are formed in the same manner as described above with reference to FIGS. 1 through 8.

Hereinafter, referring to FIG. 16, a method of fabricating the semiconductor integrated circuit device according to an exemplary embodiment of the present invention will now be described in detail. FIG. 16 is a cross-sectional view of a semiconductor integrated circuit device according to an exemplary embodiment of the present invention. The semiconductor integrated circuit device of FIG. 16 has a similar structure to the semiconductor integrated circuit device of FIG. 1 and FIG. 9.

Referring to FIG. 16, a substrate 100 is divided into a cell region A and a peripheral circuit region B. A recess channel transistor 600 is formed in the cell region A, and first and second planar channel transistors 700 and 800 are formed in the peripheral circuit region B.

A first gate insulation layer 620 is formed on the inner surface of a recess channel 610 of the recess channel transistor 600, and second and third gate insulation layers 720 and 820 are formed on the top surface of the substrate 100 in the peripheral circuit region B. The gate insulation layers 620, 720, and 820 may be formed of silicon oxide (SiO,) or silicon oxynitride (SiON).

The recess channel transistor 600 includes the first gate insulation layer 620, the first planar channel transistor 700 includes the second gate insulation layer 720, and the second planar channel transistor 800 includes the third gate insulation layer 820. The first gate insulation layer 620 may be thicker than the second gate insulation layer 720, and the second gate insulation layer 720 may be thicker than the third gate insulation layer 820.

Gates 630, 730, and 830 are provided on the gate insulation layers 620, 720, and 820, respectively. The gate 630 is formed in the recess channel transistor 600 to fill the recess channel 610 and to protrude over the recess channel 610. The gates 730 and 830 are stacked on the second and third gate insulation layers 720 and 820, respectively, and form the first and second planar channel transistors 700 and 800, respectively. Here, the gate 630 of the recess channel transistor 600 is self-aligned with both sidewall of the recess channel 610. That is, the gate 630 protruding over the recess channel 610 is aligned with a pair of imaginary straight lines extending above both sidewalls of the recess channel 610.

Further, the gates 730 and 830 of the first and second planar channel transistors 700 and 800 have lower portions that may be undercut. In other words, the lower portions of the gates 730 and 830 may be undercut so that widths of the undercut lower portions of the gates 730 and 830 are approximately the same as those of the gate insulation layers 720 and 820, respectively.

In addition, edges of the lower portions of the gates 730 and 830 may be generally rounded. In other words, the lower protruding portions of lateral sides of the gates 730 and 830 formed from the undercut may be generally rounded.

The thicknesses of the gate insulation layers 620, 720, and 820 may be made to be different from one another for the purpose of making operating voltages and electrical characteristics of the respective recess channel transistors 600, 700, and 800 different from one another.

If the protruding portions of the gates 730 and 830 of the planar channel transistors 700 and 800 are generally rounded, it may also be possible to prevent a strong electric field from being concentrated on the edges of the gates 730, 830. Therefore, it may be possible to stabilize the operation of the planar channel transistors 700 and 800 and reduce leakage current. In addition, it is possible to secure a sufficient amount of time to refresh the planar channel transistors 700 and 800, thereby reducing power consumption.

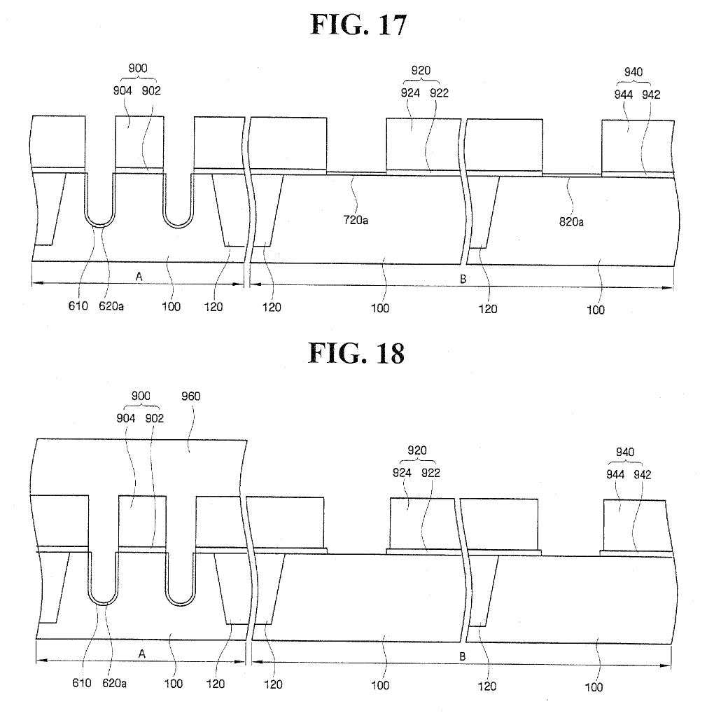

Hereinafter, a method of fabricating the semiconductor integrated circuit device of FIG. 16 according to an exemplary embodiment of the present invention will now be described in detail with reference to FIGS. 17 through 24.

Referring to FIGS. 17 through 24, a substrate 100 is divided into an active region and an inactive region, and recess channels 610 are formed using an insulation mold 900 with openings formed therein in the same manner as described above with reference to FIGS. 3 through 5.

Referring to FIG. 17, a first oxide layer 620a is formed on the inner surface of the recess channel 610 exposed through the openings formed in the insulation mold 900, a first oxide layer 720a is formed on the top surface of the substrate 100 exposed through an opening formed in an insulation mold 920, and a first oxide layer 820a is formed on the top surface of the substrate 100 exposed through an opening formed in an insulation mold 940.

Thereafter, referring to FIG. 18, photoresist 960 is applied onto the top surface of the substrate 100 in the cell region A, and an isotropic etching operation is performed on the substrate 100 to eliminate the first oxide layers 720a and 820a. If part of the insulation mold 920 or 940 is formed of an oxide layer, the insulation mold 920 or 940 may also be partially etched with the first oxide layer 720a or 820a. In other words, if the insulation mold 920 or 940 has a 2-layered structure consisting of a lower insulation mold 922 or 942 and an upper insulation mold 924 or 944 formed of an oxide layer, the lower insulation mold 922 or 942 may serve as an etching stopper layer and part of the upper insulation mold 924 or 944 may be etched with the second and third gate insulation layer 720a and 820a so that the width of the opening formed in the insulation mold 920 or 940 may be increased. Accordingly, the insulation mold 920 or 940 may have a step structure as illustrated in FIG. 18.

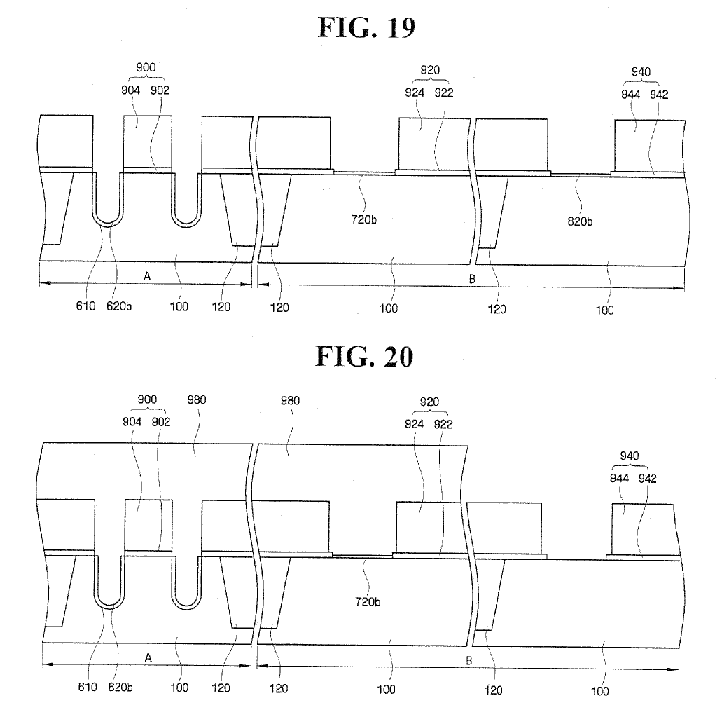

Thereafter, referring to FIG. 19, the photoresist 970 is eliminated from the cell region A through, for example, ashing. Further, an oxidation operation may be performed on a second oxide layers 620b, 720b, and 820b. Since the second oxide layer 620b in the cell region A is obtained through two oxidation operations and the second oxide layer 720b, 820b in the peripheral circuit region B is obtained through one oxidation operation, the second oxide layer 620b is thicker than the second oxide layer 720b, 820b.

Thereafter, referring to FIG. 20, photoresist 980 is applied on portions of the substrate 100 in the cell region A and on portions of the substrate 100 in the peripheral circuit region B on which a first planar channel transistor 700 is to be formed. Thereafter, an isotropic etching operation is performed on the substrate 100, thereby eliminating the second oxide layer 820b to secure a space for a second planar channel transistor 800 to be formed. If the upper insulation mold 944 is formed as an oxide layer, part of the upper insulation mold 944 may be etched with the second oxide layer 820b. Therefore, the width of the opening in the insulation mold 940, in which the second planar channel transistor 800 is to be formed becomes greater than the width of the opening in the insulation mold 920 in which the first planar channel transistor 700 is to be formed.

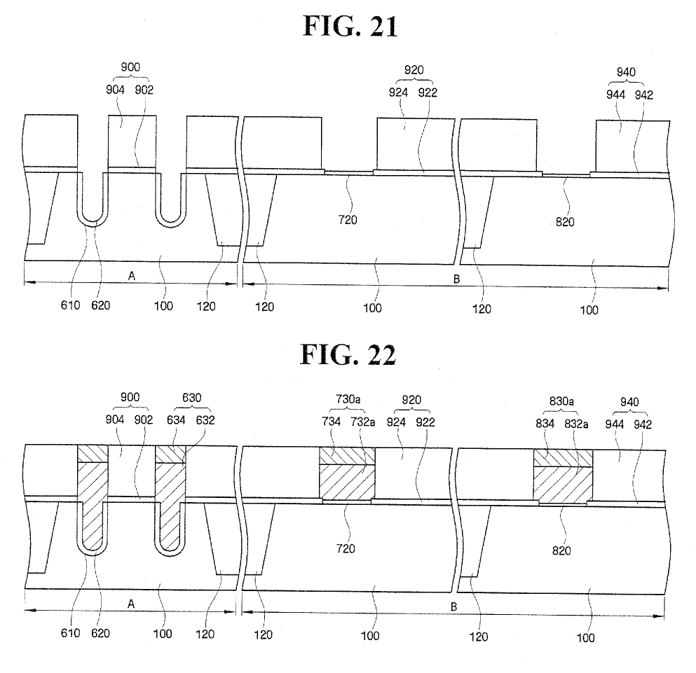

Next, referring to FIG. 21, the photoresist 980 is eliminated through, for example, ashing. Further, an oxidation operation may be performed, forming first, second, and third gate insulation layers 620, 720, and 820. In detail, the first gate insulation layer 620 is obtained through 3 oxidation operations, the second gate insulation layer 720 is obtained through 2 oxidation operations, and the third gate insulation layer 820 is obtained through a single oxidation operation. Therefore, the first gate insulation layer 620 may be thicker than the second gate insulation layer 720, and the second gate insulation layer 720 may be thicker than the third gate insulation layer 820.

Referring to FIG. 22, gates 630, 730a, and 830a are formed in a self-aligned manner to substantially completely fill the openings in the insulation molds 900, 920, and 940. In detail, the gates 630 are formed in the cell region A to substantially completely fill the openings formed in the insulation mold 900, the gate 730a is formed in the peripheral circuit region B to substantially completely fill the opening formed in the insulation mold 920, and the gate 830a is formed in the peripheral circuit region B to substantially completely fill the opening formed in the insulation mold 940. Since the openings formed in the insulation molds 920 and 940 have a step structure, the gates 730a and 830a are formed to have a step-like profile.

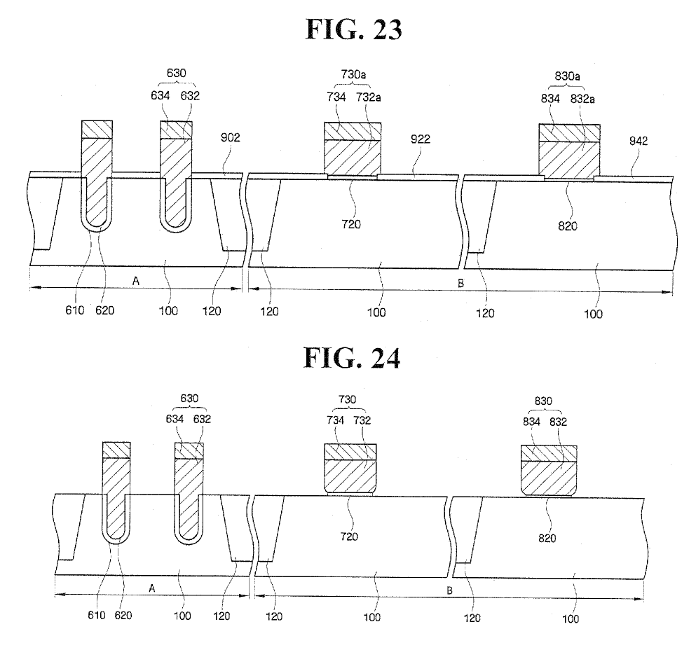

Thereafter, referring to FIG. 23, insulation molds 904, 924, and 944 are eliminated through etching. If each of the insulation molds 900, 920, and 940 has a 2-layered structure, only the upper insulation molds 904, 924, and 944 may be eliminated while keeping the lower insulation molds 902, 922, and 942 intact.

Thereafter, referring to FIG. 24, an isotropic etching operation is carried out on the substrate 100, thereby eliminating the lower insulation molds 902, 922, and 942. The isotropic etching operation is carried out using an etchant which is capable of slightly etching polysilicon layers 632, 732, and 832 as well as the lower insulation molds 902, 922, and 942.

When the lower insulation molds 902, 922, and 942 are eliminated, the polysilicon layers 632, 732, and 832 may be slightly etched. As mentioned previously, the more the target of an etching operation protrudes, the more it may be affected by an etchant. Thus, lower portions of the polysilicon layer 732 or 832 may be generally rounded in the isotropic etching operation.

Thereafter, spacers 640, 740, and 840 and then sources and drain regions 650, 750, and 850 are formed in the same manner as described above with reference to FIGS. 1 through 8.

As described above, a semiconductor integrated circuit device and method for fabricating the same according to the present invention provides at least the following advantages.

First, since gates are self-aligned, misalignment does not occur and the gates can be precisely aligned with recess channels.

Second, since the gates are formed to be precisely aligned with the respective recess channels, it is possible to secure a sufficient channel length and thus allow for the stable operation of the transistors.

Third, since protruding portions of the recess channels are generally rounded, refresh-time characteristics of transistors can be improved and power consumption can be reduced.

It is to be understood that the above-described embodiments have been provided only in a descriptive sense and will not be construed as placing any limitation on the scope of the invention. While the present invention has been particularly shown and described with reference to exemplary embodiments thereof, it will be understood by those of ordinary skill in the art that various changes in form and details may be made therein without departing from the spirit and scope of the present invention as defined by the following claims. For example, the first oxide layer 420a may be formed of other insulating materials known to one skilled in the art.

What is claimed is:

1. A semiconductor device comprising:
a substrate having a cell region and a peripheral circuit region;
a recess channel transistor formed in the cell region, the recess channel transistor including source/drain regions, a recess channel formed between the source/drain regions, a gate insulation layer formed in the recess channel, and a gate formed on the gate insulation layer in a self-aligned manner; and
a planar channel transistor formed in the peripheral circuit region, the planar channel transistor including source/drain regions, a planar channel formed between the source/drain regions, a gate insulation layer formed in the planar channel, and a gate formed on the gate insulation layer in the self-aligned manner.

2. The semiconductor device of claim 1, wherein the gate of the planar channel transistor has a portion whose width is greater than a width of the gate insulation layer of the planar channel transistor.

3. The semiconductor device of claim 1, wherein lower edges of the gate of the planar channel transistor are generally rounded.

4. The semiconductor device of claim 1, wherein the gate insulation layer of the recess channel transistor is thicker than the gate insulation layer of the planar channel transistor.

5. The semiconductor device of claim 1, wherein the planar channel transistor comprises a first planar channel transistor including a first gate insulating layer and a second planar channel transistor including a second gate insulating layer, the first gate insulating layer being thicker than the second gate insulating layer, and the gate insulating layer of the recess channel transistor being thicker that the first gate insulating layer.

6. A semiconductor device comprising:
a substrate including a cell region and a peripheral circuit region;
a recess channel transistor formed in the cell region, the recess channel transistor including
a recess channel formed in the substrate,
a gate insulation layer formed on the surface of the recess channel,
a gate formed in a self-aligned maimer on the gate insulation layer to fill the recess channel and protrude above a top surface of the substrate, the gate including a polysilicon layer and a metallic layer formed on the polysilicon layer,
source/drain regions formed in the substrate on both sides of the gate, and
gate spacers formed on sidewalls of the gate; and
a planar channel transistor formed in the peripheral circuit region, the planar channel transistor including
a gate insulation layer formed on a portion of the substrate,
a gate formed in a self-aligned manner on the gate insulation layer, the gate including a polysilicon layer and a metallic layer formed on the polysilicon layer,
source/drain regions formed in the substrate on both sides of the gate, and
gate spaces formed on sidewalls of the gate.

7. The semiconductor device of claim 6, wherein lower edges of the gate of the planar channel transistor are undercut such that an upper portion of the gate has a larger width than a lower portion of the gate, where the undercut lower edges of the gate are generally rounded.

8. The semiconductor device of claim 6, wherein the gate insulation layer of the recess channel transistor is thicker than the gate insulation layer of the planar channel transistor.

9. The semiconductor device of claim 6, wherein the planar channel transistor comprises a first planar channel transistor including a first gate insulating layer and a second planar channel transistor including a second gate insulating layer, the first gate insulating layer being thicker than the second gate insulating layer, and the gate insulating layer of the recess channel transistor being thicker that the first gate insulating layer.

10. A method of fabricating a semiconductor device comprising:
providing a substrate on which a cell region and a peripheral circuit region are defined;
forming an insulation mold with openings on the substrate;
forming a recess channel by etching the substrate in the cell region by using the insulation mold as an etching mask;
forming gate insulation layers on the surface of the recess channel in the cell region and on the top surface of the substrate in the peripheral circuit region;
forming a gate on the gate insulation layer in the recess channel in a self-aligned manner and a gate on the gate insulation layer in the peripheral circuit region in a self-aligned manner, where each gate is formed to substantially completely fill the openings in the insulation mold;
eliminating the insulation mold; and
forming a recess channel transistor in the cell region and forming a planar channel transistor in the peripheral circuit region by forming source/drain regions in the substrate on both sides of the gates, respectively.

11. The method of claim 10, wherein a portion of the gate of the planar channel transistor is wider than the gate insulation layer of the planar channel transistor.

12. The method of claim 10, wherein lower edges of the gate of the planar channel transistor are generally rounded.

13. The method of claim 10, wherein the gate insulation layer of the recess channel transistor is thicker than the gate insulation layer of the planar channel transistor.

14. The method of claim 10, wherein the gate insulation layers are formed by performing at least one oxidation operation.

15. The method of claim 14, wherein the performing of the at least one oxidation operation comprises:
performing a first oxidation operation to form first oxide layers on the surface of the recess channel in the cell region and on the top surface of the substrate in the peripheral circuit region;
eliminating the first oxide layer from the peripheral circuit region; and
performing a second oxidation operation to form a second oxide layer on the first oxide layer in the cell region and on the top surface of the substrate in the peripheral circuit region, wherein the first and second oxidation layers in the cell region form the gate insulation layer in the cell region and the second oxidation layer in the peripheral circuit region forms the gate insulation layer in the peripheral circuit region.

16. The method of claim 15, wherein eliminating the first oxide layer from the peripheral circuit region comprises:
forming a photoresist pattern over the recess channel and at least a portion of the insulation mold in the cell region;
etching the first oxide layer from the peripheral circuit region; and removing the photoresist pattern.

17. The method of claim 15, wherein the insulation mold includes a lower insulation mold layer and an upper insulation mold layer, a portion of the upper insulation mold layer in the peripheral circuit region being removed with the first oxide layer such that the profile of the insulation mold in the peripheral circuit region has a step structure.

18. The method of claim 14, wherein the peripheral circuit region is divided into a first region and a second region, and the performing of the at least one oxidation operation comprises:
performing a first oxidation operation to form first oxide layers on the surface of the recess channel in the cell region and on the top surface of the substrate in the first and second peripheral circuit regions;
eliminating the first oxide layer from the first and second peripheral circuit regions;
performing a second oxidation operation to form a second oxide layer on the first oxide layer in the cell region and on the top surface of the substrate in the first and second peripheral circuit regions;
eliminating the second oxide layer from the second peripheral circuit region; and
performing a third oxidation operation to form a third oxide layer on the second oxide layer in the cell region, on the second oxide layer the first peripheral circuit region, and on the top surface of the substrate in the second peripheral circuit region, wherein the first, second, and third oxidation layers in the cell region form the gate insulation layer in the cell region, the second and third oxidation layers in the first peripheral circuit region form the gate insulation layer in the first peripheral circuit region, and the third oxidation layer in the second peripheral circuit region forms the gate insulation layer in the second peripheral circuit region.

19. The method of claim 18, wherein eliminating the first oxide layer from the first and second peripheral circuit regions comprises:
forming a photoresist pattern over the recess channel and at least a portion of the insulation mold in the cell region;
etching the first oxide layer in the first and second peripheral circuit regions; and
removing the photoresist pattern.

20. The method of claim 18, wherein eliminating the second oxide layer from the second peripheral circuit region comprises:
forming a photoresist pattern over the recess channel and at least a portion of the insulation mold in the cell region and over the second oxidation layer and at least a portion of the insulation mold in the first peripheral circuit region;
etching the second oxide layer in the second peripheral circuit region; and
removing the photoresist pattern.

21. The method of claim 18, wherein the insulation mold includes a lower insulation mold layer and an upper insulation mold layer, a first portion of the upper insulation mold layer in the first and second peripheral circuit regions being removed with the first oxide layer and a second portion of the upper insulation mold layer in the second peripheral circuit region being eliminated with the second oxide layer such that the profile of the insulation mold in the first and second peripheral circuit regions has a step structure.

22. The method of claim 10, wherein the height of the insulation mold is greater than that of a gate to be formed.

23. The method of claim 10, wherein the insulation mold is formed of an oxide layer.
